(19) United States
(12) Patent Application Publication
(10) Pub. No.: US 2014/0046171 A1
(43) Pub. Date: Feb. 13, 2014

(54) METHOD AND APPARATUS FOR IDENTIFYING AT LEAST ONE RADIATION-ATTENUATING IMPLANT FOR MEDICAL MR-PET IMAGING

(71) Applicant: SIEMENS AKTIENGESELLSCHAFT, Munich (DE)

(72) Inventor: Sebastian SCHMIDT, Weisendorf (DE)

(21) Appl. No.: 13/928,536

(22) Filed: Jun. 27, 2013

(30) Foreign Application Priority Data
Aug. 7, 2012 (DE) 102012214012.3

(51) Int. Cl. G01R 33/48

(52) U.S. Cl. CPC G01R 33/481
USPC 600/411

(57) ABSTRACT

A method is disclosed. In at least one embodiment, the method includes segmentation of an implant present in a target object by diverging the attenuation of the MR signals caused by the implant from a threshold value; determination of a suitable attenuation coefficient and consideration of the attenuation coefficient in the PET imaging for the correct PET representation of the target object including the implant. The attenuation coefficient can thereby by determined dependent on the material of the implant.

### PRIORITY STATEMENT

The present application hereby claims priority under 35 U.S.C. §119 to German patent application number DE 102012214012.3 filed Aug. 7, 2012, the entire contents of which are hereby incorporated herein by reference.

### FIELD

At least one embodiment of the invention generally relates to a method and/or apparatus for identifying at least one radiation-attenuating implant for medical MR-PET imaging.

### BACKGROUND

In combined MR-PET systems (MR=magnetic resonance; PET=positron emission tomography), the attenuation correction data (what is known as M-MAP) is generated for the correction of the PET data using MR. Since with MR, unlike with CT (computed tomography), there is no direct correlation between signal and PET attenuation, this data must be generated indirectly. The following methods for calculating the μ-MAP from the MR data are conceivable:
Segmentation: Different compartments are segmented in the MR image (e.g. soft tissue, air, fat or bones). These are assigned attenuation values. Methods with varying numbers of compartments (e.g. 2-4) are known for this purpose.
Atlas or registry-based methods: An atlas with a predefined attenuation map is registered with the MR images (flexible or rigid). The result is what is known as the attenuation map which is known by way of example from DE 102004043889.

Tissues with rapid signal decay (bound protons, such as bones for example) can be made visible and able to be included in the attenuation by employing imaging with ultra-short echo (UTE) times. A procedure of this type is known from DE 102007013564.
For device components and accessories (e.g. receiver coils), databases with attenuation values are used. If the component is not stationary, the position should additionally be determined, either from the MR image or by suitable sensors. A method of this type is described by way of example in DE 102007044874.

The above methods are well-suited to correcting the anatomy of the patient, and accessories, for example components of the imaging system. They fail however to correct implants which are located inside the patients. In this regard, hip prostheses (endoprostheses) are particularly problematic, in which a part of the thigh and the pelvic bone have been replaced with a prosthesis. Since these are made of metal with high radiation densities (e.g. titanium, stainless steel or cobalt-chromium-molybdenum alloys) and are relatively big, they produce strong radiation attenuation and thus a significant distortion of the PET signals, if this attenuation is not taken into account. Hip prostheses are also often implanted on both sides, thereby compounding the problem even more. Distortion of the result is especially possible in MR-PET examinations of the pelvis (e.g. in prostate or rectal carcinoma there is the question of attack on pelvic lymph nodes).

Due to the demographic factor, the number of implanted prostheses will continue to increase and since even younger patients are now receiving implanted prostheses, the problem of distortion described above will worsen. For other implants (shoulder, knee prostheses, pacemakers, etc.) the problem is the same in principle, but due to their locations (i.e. in the knee) or their low attenuation (e.g. pacemakers) these have a lesser impact.

### SUMMARY

At least one embodiment of the invention is directed to an improved method of identification of implants for medical MR-PET imaging.

At least one embodiment of the invention is achieved with the method or the apparatus. Advantageous embodiments of the invention are the subject matter of the dependent claims or may be inferred from the following description and the example embodiments.

The subject matter of at least one embodiment of the invention is the identification of radiation-attenuating implants in the body of a patient as well as determining the shape and position of the implant using MR methods and taking these into account for the attenuation correction of the PET image data. Better and more accurate PET imaging via an MR-PET system is thereby realized, specifically for lesions in the pelvis and one or two-side hip prostheses.

The related inventive method, of at least one embodiment, embodied for the identification of at least one radiation-attenuating implant for medical MR-PET imaging comprises:
a) Segmentation of an implant present in a target object by diverging the attenuation of the MR signals caused by the implant from a predetermined threshold value,
b) Determination of a suitable attenuation coefficient and
c) Consideration of this attenuation coefficient in the PET imaging for the correct PET representation of a target object comprising the implant.

A further aspect of at least one embodiment of the invention provides a device for identifying at least one such radiation-attenuating implant, which provides in each case corresponding to the above-mentioned method, at least one device for segmentation or at least one device for determining the appropriate attenuation coefficient and at least one device for taking this attenuation coefficient into account in PET imaging.

### BRIEF DESCRIPTION OF THE DRAWINGS

Further advantages, details and developments of the invention will emerge from the following description of example embodiments in conjunction with the drawings, in which:

FIG. 1 shows the schematic illustration of a combined positron emission tomography and magnetic resonance tomography (MRT) device,

FIG. 2 shows an MR image of an object under examination,

FIG. 3 shows a flow diagram of the inventive procedure.

### DETAILED DESCRIPTION OF THE EXAMPLE EMBODIMENTS

The present invention will be further described in detail in conjunction with the accompanying drawings and embodiments. It should be understood that the particular embodiments described herein are only used to illustrate the present invention but not to limit the present invention.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

The subject matter of at least one embodiment of the invention is the identification of radiation-attenuating implants in the body of a patient as well as determining the shape and position of the implant using MR methods and taking these into account for the attenuation correction of the PET image data. Better and more accurate PET imaging via an MR-PET system is thereby realized, specifically for lesions in the pelvis and one or two-side hip prostheses.

The related inventive method, of at least one embodiment, embodied for the identification of at least one radiation-attenuating implant for medical MR-PET imaging comprises:
a) Segmentation of an implant present in a target object by diverging the attenuation of the MR signals caused by the implant from a predetermined threshold value,
b) Determination of a suitable attenuation coefficient and
c) Consideration of this attenuation coefficient in the PET imaging for the correct PET representation of a target object comprising the implant.

The attenuation coefficient can preferably be determined dependent on the material of the implant. In addition it is possible for a PET-applicable average value of attenuation coefficient to be assumed.

It is expedient for a database to be available in which the attenuation coefficients for a particular type of implant are arranged, from which the appropriate attenuation coefficient can be called up with the aid of the shape of the implant determined in the step above.

The material of the implant can also be manually entered by a user. If necessary, the corresponding attenuation coefficient can be called up from a database or the same database again. Furthermore, it is conceivable that the attenuation coefficient can be determined by means of MR data, with which the magnetic properties of the implant can be deduced.

In an advantageous manner, the extent of the susceptibility artifacts of the MR data can be used to determine the attenuation coefficients.

A further aspect of at least one embodiment of the invention provides a device for identifying at least one such radiation-attenuating implant, which provides in each case corresponding to the above-mentioned method, at least one device for segmentation or at least one device for determining the appropriate attenuation coefficient and at least one device for taking this attenuation coefficient into account in PET imaging.

A combined MRT/PET device consists of an MRT device and a PET device with an integrated PET device part.

For the sake of clarity, the mandatory coils in an MRT device which generate a magnetic background in an examination space are not shown. In order to generate independent magnetic field gradients which are parallel to one another in the directions x, y, z according to a coordinate plane, an MRT device comprises a gradient coil system G, which is illustrated here only simplified and schematically. An MR magnet MR-M is also assigned to the MRT device and a high-frequency antenna arrangement or MR send/receive antenna A for generating excitation pulses in the examination space and/or for receiving magnetic resonance signals from the object under examination U or patient from the examination space. The PET device part in this example embodiment comprises four gamma ray detectors D, with which the PET radiation emitted by the object under examination is detected and with the aid of the electronic units assigned to the gamma ray detectors D, a corresponding electrical signal can be generated.

The electrical PET, PET-S and MR signals MR-S arrive at an image processor B connected to the MR-PET device by a signal line or radio link. The PET and MRT sectional images obtained by the image processor are transmitted to a process computer which preferably features a screen display, by which the sectional images are superimposed by computer and can be output as a combined PET-MRT image.

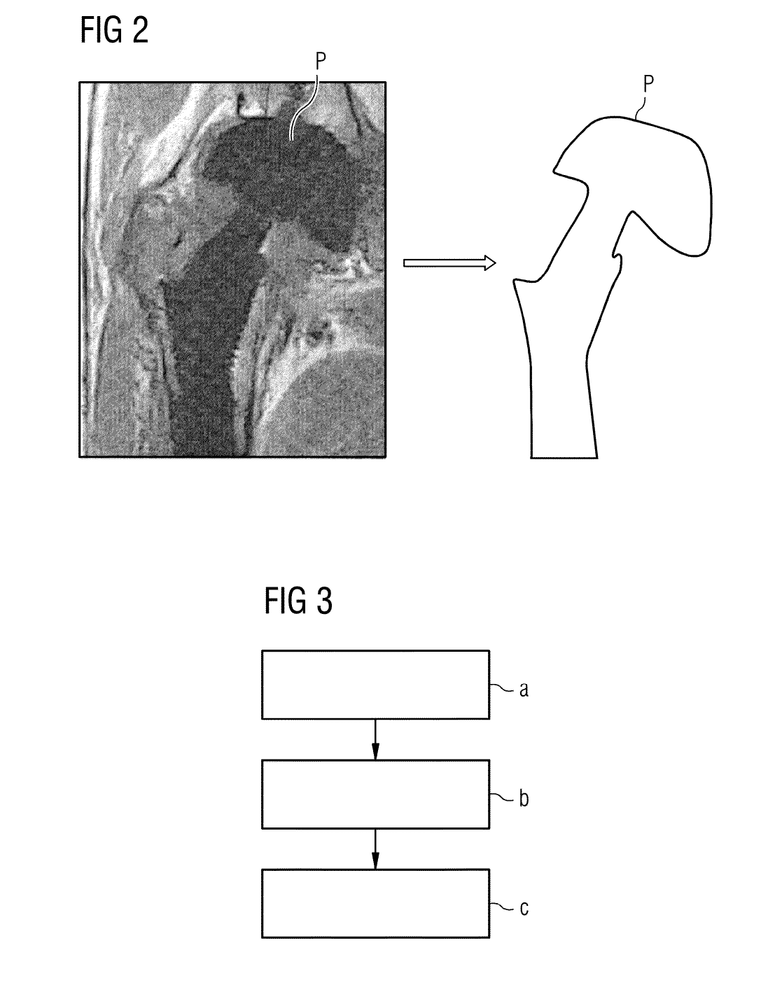

The left-hand panel of FIG. 2 shows by way of example an MR image of an object under examination, in the example embodiment a hip prosthesis. Signal loss (i.e. the attenuation of the MR signal deviates too far from a threshold value) within the metallic prosthesis enables a segmentation of the prosthesis. The right-hand panel of FIG. 2 merely shows a schematic of the hip prosthesis, wherein the prosthesis in the μ-map is input with an assumed attenuation value.

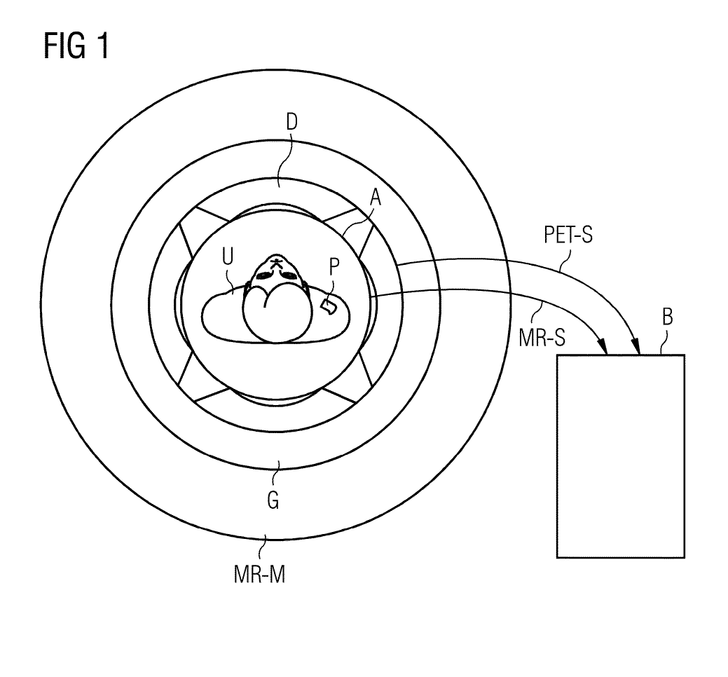

An apparatus is conceivable, in particular such an image processor B as may perform the embodiment of the inventive method steps described below and which features corresponding device(s) for carrying out the described method. As indicated in FIG. 1, this image processor can be connected to the MR-PET device or integrated into this device.

FIG. 3 shows the steps a to c of the inventive procedure:
a: Segmentation of an implant present in a target object by diverging the attenuation of the MR signals caused by the implant from a predetermined threshold value. The segmentation of an implant present in a target object can also take place when the threshold value of the MR signal is exceeded or not met by the attenuation caused by the implant, depending on how the threshold value has been specified or defined.
b: Determination of a suitable attenuation coefficient and
c: Consideration of this attenuation coefficient in the PET imaging for the correct PET representation of a target object comprising the implant.

According to an embodiment of the invention, the prosthesis or the implant is identified in the MR image and its attenuation values or attenuation coefficients are taken into account in the attenuation correction (μ-MAP).

Metallic implants in MR data records can generally be located owing to the resulting artifacts, e.g. in DE 102009033606 (the entire contents of which are hereby incorporated herein by reference) a method is described showing how a metallic body may be identified and even quantified by the susceptibility artifacts emerging therefrom.

When imaging the outer shape of an implant, the artifacts absorb the image to the extent that the shape is no longer recognizable. This can be remedied by using special sequences which compensate for this kind of distortion. Sequences of this type are described for example in DE 102010062290, the entire contents of which are hereby incorporated herein by reference.

Therefore the presence of a prosthesis or an implant is initially established via suitable MR (e.g. as described above) and via an appropriate method an image data record of the prosthesis or the implant is created, which illustrates the shape and location of the implant. The prosthesis itself can be very simply segmented in the image data record by means of thresholding, since the MR signal within the material practically assumes a value of zero.

In order to correctly reproduce the implant in the μ-MAP, an attenuation coefficient should also be assigned which is specific to the material. The following possibilities exist for that purpose:
An average attenuation coefficient can be assumed dependent on the actual material or substance.
The type or kind of implant can be identified from a database on the basis of the shape of the prosthesis or the implant.
The user can be required to manually input the implant material into the system. The material is usually recorded in the documents accompanying the implant or prosthesis (prosthesis pass).
The magnetic properties and therefore the material of the prosthesis can be deduced with the aid of MR data (extent of the susceptibility artifacts).

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A method for identifying at least one radiation-attenuating implant for medical magnetic resonance (MR) and positron emission tomography (PET) imaging, the method comprising:
segmenting an implant present in a target object by diverging attenuation of MR signals caused by the at least one radiation-attenuating implant from a threshold value;
determining a suitable attenuation coefficient; and
considering the attenuation coefficient in the PET imaging for a correct PET representation of the target object including the at least one radiation-attenuating implant.

2. The method of claim 1, wherein the attenuation coefficient is determined dependent on a material of the implant.

3. The method of claim 1, wherein a PET-applicable average value of the attenuation coefficient is assumed.

4. The method of claim 1, wherein the attenuation coefficient is defined via a shape of at least one radiation-attenuating the implant determined during the segmenting and wherein recalling of the attenuation coefficient of the at least one radiation-attenuating implant with the aid of the determined shape from an available implant database is defined which provides an assignment of an attenuation coefficient according to a shape of an implant.

5. The method of claim 1, wherein the attenuation coefficient is determinable by a user manually inputting the implant material.

6. The method of claim 4, wherein the assignment of the attenuation coefficient for a manually entered implant material takes place with the aid of the available implant database.

7. The method of claim 1, wherein the attenuation coefficient is determined with the aid of MR data, on the basis of which the magnetic properties of the at least one implant is deducible.

8. The method of claim 1, wherein an extent of susceptibility artifacts in the MR data is useable for determining the attenuation coefficient.

9. An apparatus for identifying at least one radiation-attenuating implant for medical magnetic resonance (MR) and positron emission tomography (PET) imaging, comprising:
a processor
configured to segment an implant present in a target object by diverging attenuation of an MR signal caused by the at least one radiation-attenuating implant from a threshold,
configured to determine a suitable attenuation coefficient, and
configured to take the attenuation coefficient into account in the PET imaging, for correct PET illustration of a target object including the at least one radiation-attenuating implant.

10. The apparatus as claimed in claim 9, characterized in that the attenuation coefficient is able to be determined dependent on the material of the implant.

11. The method of claim 2, wherein a PET-applicable average value of the attenuation coefficient is assumed.

12. The method of claim 2, wherein the attenuation coefficient is defined via a shape of at least one radiation-attenuating the implant determined during the segmenting and wherein recalling of the attenuation coefficient of the at least one radiation-attenuating implant with the aid of the determined shape from an available implant database is defined which provides an assignment of an attenuation coefficient according to a shape of an implant.

13. The method of claim 3, wherein the attenuation coefficient is defined via a shape of at least one radiation-attenuating the implant determined during the segmenting and wherein recalling of the attenuation coefficient of the at least one radiation-attenuating implant with the aid of the determined shape from an available implant database is defined which provides an assignment of an attenuation coefficient according to a shape of an implant.
